(19) United States
(12) Patent Application Publication
(10) Pub. No.: US 2013/0304410 A1
(43) Pub. Date: Nov. 14, 2013

(54) SERVER AND METHOD FOR TESTING SENSORS OF THE SERVER

(71) Applicants: HONG FU JIN PRECISION INDUSTRY (ShenZhen) CO., LTD., (US); HON HAI PRECISION INDUSTRY CO., LTD., New Taipei (TW)

(72) Inventors: Xiao LIANG, Shenzhen (CN); Ming LI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (TW)

(21) Appl. No.: 13/714,549

(22) Filed: Dec. 14, 2012

(30) Foreign Application Priority Data
May 10, 2012 (CN) 201210143118.0

(51) Int. Cl. G01D 18/00; G01P 21/02; G01R 35/00; G06F 15/00; G01K 15/00

(52) U.S. Cl. CPC G01D 18/00; G06F 15/00; G01K 15/007; G01R 35/00; G01P 21/02
USPC 702/116

(57) ABSTRACT

In a method for testing sensors of a server, the method obtains serial numbers of each of the sensors from a board management controller (BMC) of the server using an intelligent platform management interface (IPMI) service of the server, and modifies lower and upper critical values to generate first and second system event logs even during normal working of the components subject to sensing. The method records a confirmed and tested status of each of the sensors if the first system event log and the second system log are right.

### BACKGROUND

1. Technical Field

Embodiments of the present disclosure relate to sensors management and methods, and more particularly to a server, a storage medium, and a method for testing sensors of the server.

2. Description of Related Art

A sensor of a server monitors status of a component of the server, where the component may be a fan, a hard disk, a CPU, for example, and where the sensor may be a speed sensor, a temperature sensor, a voltage sensor, for example. In testing the sensors of the server, a component of the server is stressed such that a value read from the component by the sensor exceeds a threshold value of the sensor, in order to generate a system event log. But it is dangerous for the component to work in the status as described, for example, a CPU may be damaged by excessive temperature when the CPU is worked into a temperature which is too high. The threshold value as described above functions like an alarm that warns that the component on the server is in danger, and may be classed as lower critical value and upper critical value. Taking a voltage sensor as an example, the upper critical value presents a voltage which is too high and the lower critical value presents a voltage which is too low, which is dangerous for the component of the server.

### BRIEF DESCRIPTION OF THE DISPLAYINGS

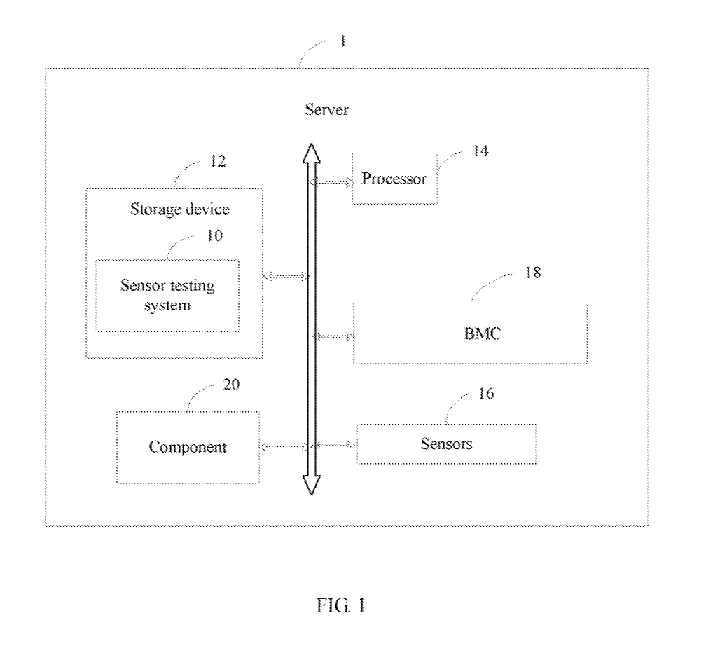

FIG. 1 is a block diagram of one embodiment of a server including a sensor testing system.

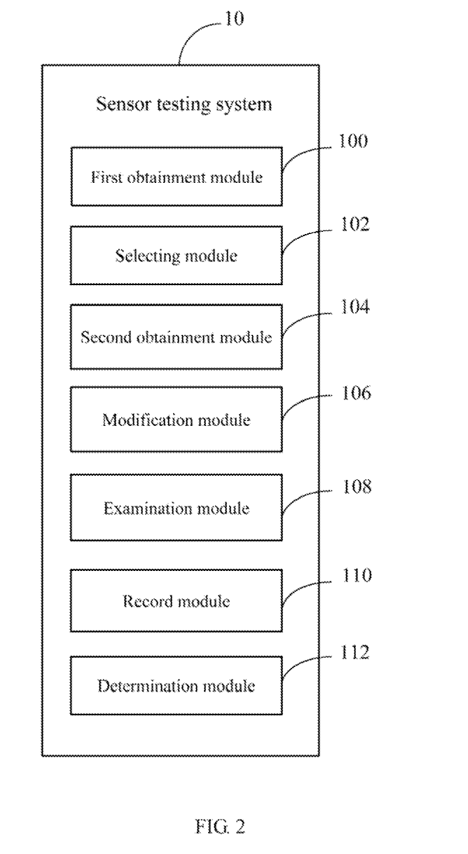

FIG. 2 is a block diagram of one embodiment of function modules of the sensor testing system in FIG. 1.

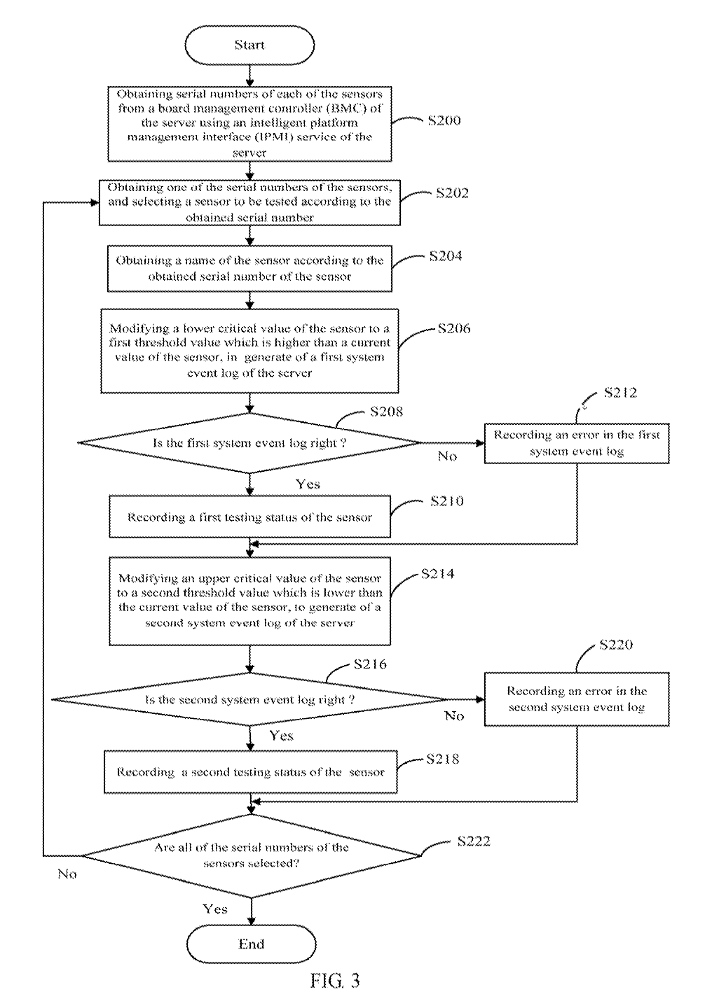

FIG. 3 illustrates a flowchart of one embodiment of a method for testing sensors of the server in FIG. 1.

### DETAILED DESCRIPTION

In general, the word “module”, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory computer-readable medium or other storage device. Some non-limiting examples of non-transitory computer-readable media include CDs, DVDs, BLU-RAY, flash memory, and hard disk drives.

FIG. 1 is a block diagram of one embodiment of a server 1 including a sensor testing system 10. In the embodiment, the server 1 includes a storage device 12, a processor 14, one or more sensors 16, a baseboard management controller (BMC) 18 and an exemplary component 20. The component 20 may be a fan, a hard disk, or any other component of the server 1.

The storage device 12 may include any type(s) of non-transitory computer-readable storage medium, such as a hard disk drive, a compact disc, a digital video disc, or a tape drive. In the embodiment, the storage device 12 stores the computerized code of the function modules of the sensor testing system 10.

The processor 14 may include a processor unit, a microprocessor, an application-specific integrated circuit (ASIC), and a field programmable gate array (FPGA), for example.

In one embodiment, the sensor testing system 10 includes a plurality of function modules (see FIG. 2 below), which include computerized codes when executed by the processor 14, to provide a method for testing the one or more sensors 16 of the server 1.

Each of the sensors 16 is integrated on the BMC 18, and monitors a status of the component 20 of the server 1. Each of the sensors 16 may be a temperature sensor, a voltage sensor, or a speed sensor, for example. The status of the component 20 may indicate a temperature, a voltage, a rotation speed of the component 20, or other parameters indicating the status of the component 20.

The BMC 18 stores characteristic data of each of the sensors 16. In the embodiment, the characteristic data of each of the sensors 16 may include a serial number and a name of each of the sensors 16.

FIG. 2 is a block diagram of one embodiment of function modules of the sensor testing system 10 of FIG. 1. In one embodiment, the sensor testing system 10 may include a first obtainment module 100, a selecting module 102, a second obtainment module 104, a modification module 106, an examination module 108, a record module 110, and a determination module 112. The modules may comprise computerized codes in the form of one or more programs that are stored in the storage device 12 and executed by the processor 14 to provide functions for implementing the modules. The functions of the function modules 100-112 are illustrated in FIG. 3 and described below.

FIG. 3 illustrates a flowchart of one embodiment of a method for testing the sensors 16 of the server 1. Depending on the embodiment, additional steps may be added, others removed, and the ordering of the steps may be changed.

In step S200, the first obtainment module 100 obtains serial numbers of each of the sensors 16 from a board management controller (BMC) of the server using an Intelligent platform management interface (IPMI) service of the server. In the embodiment, the first obtainment module 100 may obtain the serial numbers of the sensors 16 as part of the characteristic data of the sensors 16 using an intelligent platform management interface (IPMI) service of the server. For example, if the sensors 16 are voltage sensors, the characteristic data may include voltages. If the sensors 16 are temperature sensors, the characteristic data may include temperature levels.

In step S202, the selecting module 102 obtains one of the serial numbers of all the sensors 16, and selects that sensor 16 to be tested.

In step S204, the second obtainment module 104 obtains a name of the sensor 16 corresponding to the obtained serial number of the sensor 16. The obtained name of the sensor 16 is required in determining whether a system event log generated in a later procedure is correct or not.

In step S206, the modification module 106 modifies a lower critical value of the sensor 16 to a first threshold value which is higher than a current value of the sensor, to generate a first system event log of the server 1. In the embodiment, for example, the sensor 16 may be a voltage sensor, and the current value of the voltage sensor is 3.3V, the lower critical value of the voltage sensor is 2.8V. The modification module 106 modifies the lower critical value to 3.7V so that the lower critical value of the voltage sensor is now higher than the current value of the sensor 16, to generate the first system event log of the server 1.

In step S208, the examination module 108 examines whether the first system event log is correct by examining whether the first system event log includes a first keyword “lower critical value” and “obtained name”.

In step S210, if the first system event log includes the first keyword, which confirms that the first system event log is correct, the record module 110 records a first tested status of the sensor 16.

In step S212, if the first system event log does not include the first keyword, which signifies that the first system event log is not correct, the record module 110 records an error in the first system event log.

In step S214, the modification module 112 modifies an upper critical value of the sensor 16 to a second threshold value which is lower than the current value of the sensor, to generate a second system event log of the server 1. In the embodiment, for example, the sensor 16 may be a voltage sensor, and the current value of the voltage sensor is 3.3V, the upper critical value of the voltage sensor may be 3.8V. The modification module 106 modifies the upper critical value to 2.7V so that the upper critical value is lower than the current value of the sensor 16, to generate the second system event log of the server 1.

In step S216, the examination module 108 examines whether the second system event log includes a second keyword “upper critical value” and “obtained name”.

In step S218, if the second system event log includes a second keyword, which confirms that the second system event log is correct, the record module 110 records a second tested status of the sensor 16.

In step S220, if the second system event log does not include the second keyword, which signifies that the second system event log is not correct, the record module 110 records an error in the second system event log.

In step S222, the determination module 114 determines whether all of the sensors 16 have been selected and tested. If any of the sensors 16 has not been selected, step 202 is repeated. If all the sensors 16 have been selected and tested, the procedure ends.

Although certain embodiments have been specifically described, the present disclosure is not to be construed as being limited thereto. Various changes or modifications may be made to the embodiments without departing from the scope and spirit of the present disclosure.

What is claimed is:

1. A computer-implemented method for testing sensors of a server, the method comprising:
(a) obtaining serial numbers of each of the sensors from a board management controller (BMC) of the server using an intelligent platform management interface (IPMI) service of the server;
(b) obtaining one of the serial numbers of the sensors, and selecting a sensor according to the obtained serial number;
(c) obtaining a name of the sensor according to the serial number of the sensor;
(d) modifying a lower critical value of the sensor to a first threshold value that is higher than a current value of the sensor, to generate a first system event log of the server;
(e) recording a first testing status of the sensor if the first system event log includes a first keyword which presents that the first system event log is right;
(f) modifying an upper critical value of the sensor to a second threshold value which is lower than the current value of the sensor, to generate a second system event log of the server;
(g) recording a second testing status of the sensor if the second system event log includes a second keyword which presents that the second system event log is right;
(h) repeating from the step (b) to the step (g) until all of the sensors are selected to be tested.

2. The method according to claim 1, further comprises:
recording an error in the first system event log and determining that the second system event log is wrong, if the first system event log does not include the first keyword.

3. The method according to claim 1, further comprising:
recording an error in the second system event log and determining that the second system event log is wrong, if the second system event log does not include the second keyword.

4. The method according to claim 1, wherein the serial number of each of the sensors is obtained from the BMC according to characteristic data of the sensor using the IPMI service of the server.

5. The method according to claim 1, wherein the sensors are voltage sensors, temperature sensors, or speed sensors.

6. A server, comprising:
a storage device;
a board manage controller(BMC);
one or more sensors;
at least one processer; and
one or more modules that are stored in the storage device and executed by the at least one processer, the one or more modules comprising:
a first obtainment module that obtains serial numbers of each of the sensors from a board management controller (BMC) of the server using an intelligent platform management interface (IPMI) service of the server; a selecting module that obtains one of the serial numbers of the sensors, and selects a sensor according to the obtained serial number;
a second obtainment module that obtains a name of the sensor according to the o serial number of the sensor;
a modification module that modifies a lower critical value of the sensor to a first threshold value which is higher than a current value of the sensor, to generate a first system event log of the server; and
a record module that records a first testing status of the sensor if the first system event log includes a first keyword which presents that the first system event log is right;
wherein the modification module further modifies an upper critical value of the sensor to a second threshold value which is lower than the current value of the sensor, to generate a second system event log of the server; and
the record module further records a second testing status of the sensor if the second system event log includes a second keyword which presents that the second system event log is right.

7. The server according to claim 6, wherein the record module records an error in the first system event log and determines that the first system event log is wrong, if the first system event log does not include the first keyword.

8. The method according to claim 6, wherein the record module records an error in the second system event log and determines that the second system event log is wrong, if the second system event log does not include the second keyword.

9. The server according to claim 6, wherein the serial number of each of the sensors is obtained according to characteristic data of the sensor using the IPMI service of the server.

10. The server according to claim 6, wherein the sensors are voltage sensors, temperature sensors, or speed sensors.

11. A non-transitory computer-readable storage medium having stored thereon instructions that, when executed by a processor of a server, cause the processor to perform a method for testing sensors of the server, the method comprises:
(a) obtaining serial numbers of each of the sensors from a board management controller (BMC) of the server using an intelligent platform management interface (IPMI) service of the server;
(b) obtaining one of the serial numbers of the sensors, and selecting a sensor according to the obtained serial number;
(c) obtaining a name of the sensor according to the serial number of the sensor;
(d) modifying a lower critical value of the sensor to a first threshold value which is higher than a current value of the sensor, to generate a first system event log of the server;
(e) recording a first testing status of the sensor if the first system event log includes a first keyword which presents that the first system event log is right;
(f) modifying an upper critical value of the sensor to a second threshold value which is lower than the current value of the sensor, to generate a second system event log of the server;
(g) recording a second testing status of the sensor if the second system event log includes a second keyword which presents that the second system event log is right;
(h) repeating from the step (b) to the step (g) until all of the sensors are selected to be tested.

12. The storage medium according to claim 11, wherein the method further comprises:
recording an error in the first system event log and determining that the second system event log is wrong, if the first system event log does not include the first keyword.

13. The storage medium according to claim 11, wherein the method further comprises: recording an error in the second system event log and determining that the second system event log is wrong, if the second system event log does not include the second keyword.

14. The storage medium according to claim 11, wherein the serial number of each of the sensors is obtained from the BMC according to characteristic data of the sensor using the IPMI service of the server.

15. The storage medium according to claim 11, wherein the sensors are voltage sensors, temperature sensors, or speed sensors.
